(19) United States
(12) Patent Application Publication
(10) Pub. No.: US 2009/0255653 A1
(43) Pub. Date: Oct. 15, 2009

(54) System and Method for Cooling a Rack

(75) Inventors: R. Steven Mills, Cedar Park, TX (US); Ty R. Schmitt, Round Rock, TX (US)

Correspondence Address: BAKER BOTTS, LLP, 910 LOUISIANA, HOUSTON, TX, 77002-4995, US

(73) Assignee: DELL PRODUCTS L.P.

(21) Appl. No.: 12/101,510

(22) Filed: Apr. 11, 2008

(51) Int. Cl. F28D 15/00; A47F 7/00; H05K 7/20; F24H 3/02

(52) U.S. Cl. 165/104.34; 211/26; 361/695; 165/121

(57) ABSTRACT

A rack and plenum system is disclosed in which a plenum is coupled to the back of a rack. At the top of the plenum a fan assembly is installed. The fan assembly may include a pair of fans stacked on top of one another, and the rotors of the fans may spin in the opposite direction, with the blades of each fan oriented to direct air out of the top of the plenum.

### TECHNICAL FIELD

The present disclosure relates generally to computer systems and information handling systems, and, more particularly, to a system and method for cooling a rack in a data center.

### BACKGROUND

As the value and use of information continues to increase, individuals and businesses seek additional ways to process and store information. One option available to these users is an information handling system. An information handling system generally processes, compiles, stores, and/or communicates information or data for business, personal, or other purposes thereby allowing users to take advantage of the value of the information. Because technology and information handling needs and requirements vary between different users or applications, information handling systems may vary with respect to the type of information handled; the methods for handling the information; the methods for processing, storing or communicating the information; the amount of information processed, stored, or communicated; and the speed and efficiency with which the information is processed, stored, or communicated. The variations in information handling systems allow for information handling systems to be general or configured for a specific user or specific use such as financial transaction processing, airline reservations, enterprise data storage, or global communications. In addition, information handling systems may include or comprise a variety of hardware and software components that may be configured to process, store, and communicate information and may include one or more computer systems, data storage systems, and networking systems.

An information handling system may comprise a server system with a height of 1 U. Often, a number of server systems are placed in a rack that is housed in a data center. A server system generates heat during operation, and a server system will typically include multiple fans for drawing cool air into the interior of the server system and blowing heated air out of the interior of the server system.

A 1 U server system may have as many as eight or more dual rotor fans. A dual rotor fan typically includes two motors. In a rack having 42 1 U server systems (a 42 U rack), the rack will include 672 fan motors. The failure of a single fan requires that the server system be serviced, which may require that the server system be disabled, resulting in undesirable down time in the computer network of the server system. In addition, each fan consumes a significant amount of power. This power draw is exacerbated by the typical design that requires that each fan have sufficient cooling power to compensate for one or more failed fans in the server system.

### SUMMARY

In accordance with the present disclosure, a rack and plenum system is disclosed in which a plenum is coupled to the back of a rack. At the top of the plenum a fan assembly is installed. The fan assembly may include a pair of fans stacked on top of one another, and the rotors of the fans may spin in the opposite direction, with the blades of each fan oriented to direct air out of the top of the plenum. The rack and plenum system described herein is technically advantageous because the fans that direct air across the components of the computer system are not located in the interior of the computer system. Because the cooling fans for the computer system are not located in the interior of the computer system, the computer systems are easier to maintain and service, as a failure of a fan does not result in a computer system being taken offline for the purpose of repairing the failed fan. Other technical advantages will be apparent to those of ordinary skill in the art in view of the following specification, claims, and drawings.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is a side view in section of a rack and plenum system; and

FIG. 2 is a pictorial view of the rack and plenum system of FIG. 1.

### DETAILED DESCRIPTION

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communication with external devices as well as various input and output (I/O) devices, such as a keyboard, a mouse, and a video display. The information handling system may also include one or more buses operable to transmit communications between the various hardware components.

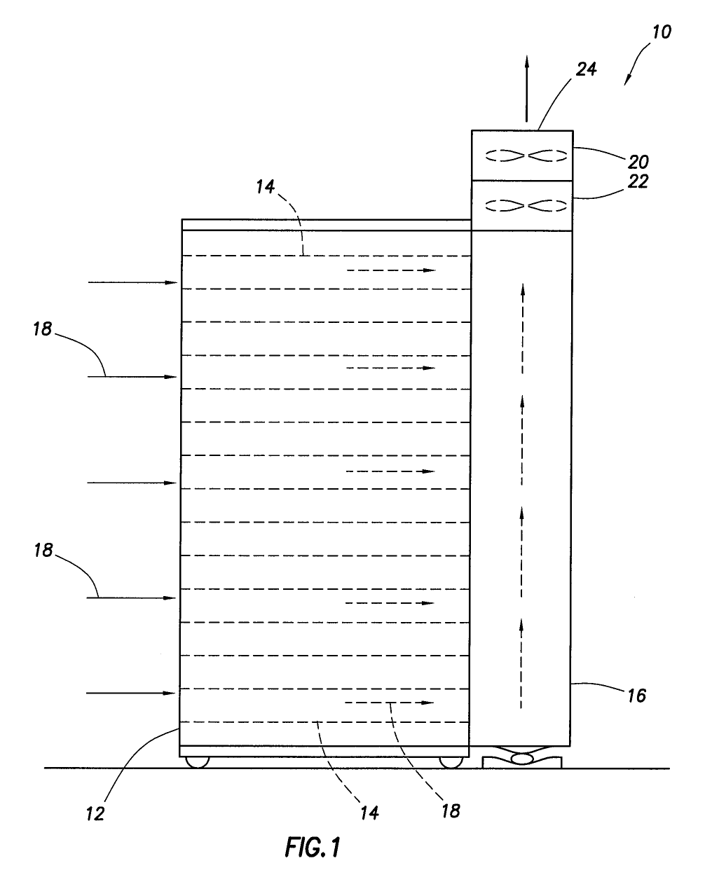

Shown in FIG. 1 is a side view, in section, of a rack system, which is indicated generally at 10. Included in the rack system 10 is a rack 12, which includes 42 1 U server systems 14. Each server system 14 includes a front 13 and a back 15. The back 15 of rack 12 is coupled to a plenum 16. Each server system 14 is in fluid communication with the plenum such that air flows through the server systems 14 in the direction of arrows 18. Air flow into the front of the server systems and out of the back of the server systems.

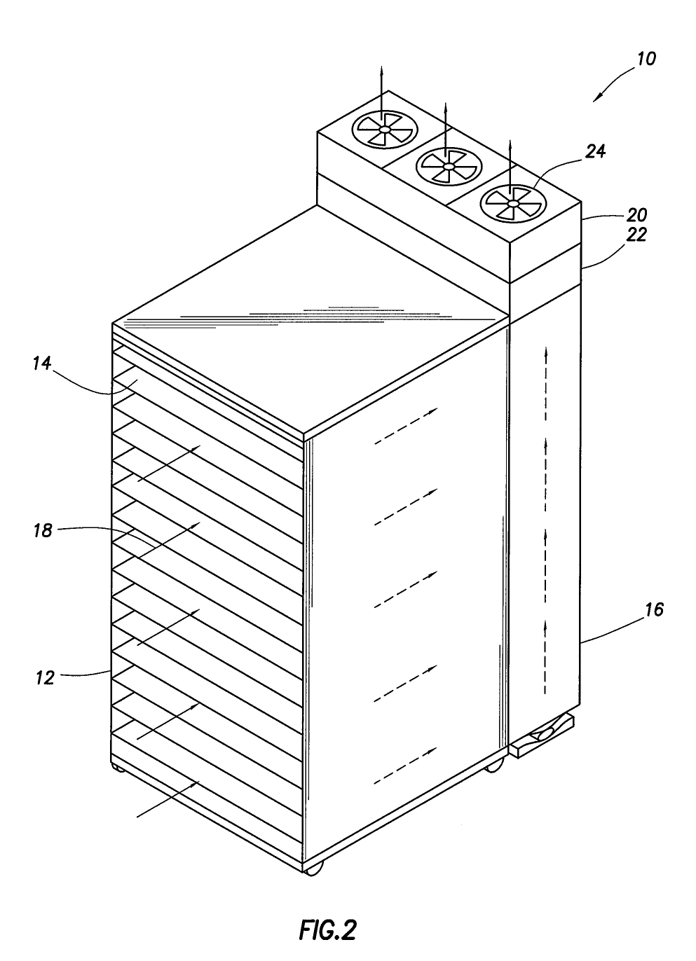

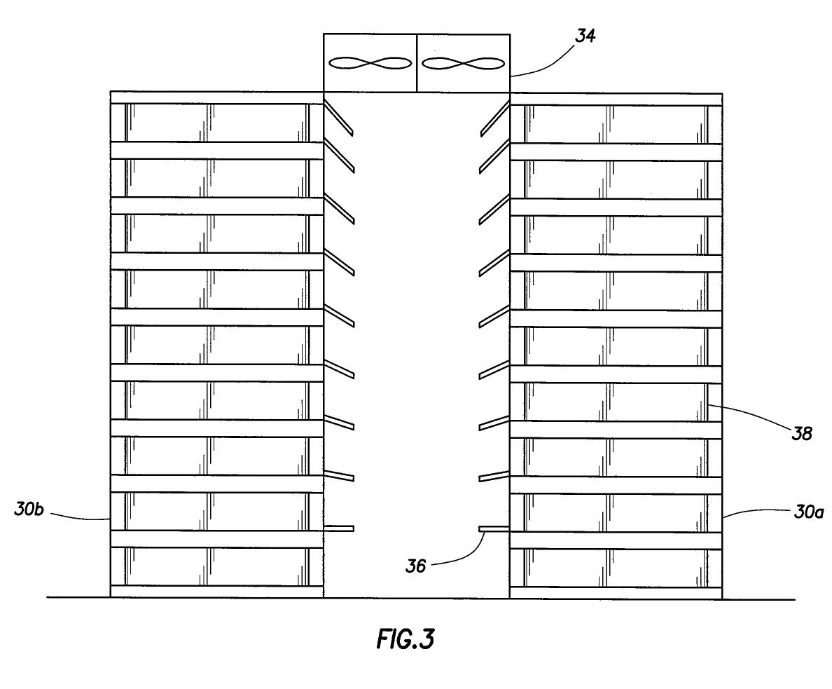

The top of plenum 16 is coupled to a set of dual rotor fans or fan assembly 20. Although only a pair of fans is shown in FIG. 1, multiple fans could be used so that the fans are arranged in an array across the width or front face (shown in FIG. 2) of the server systems 14. Dual rotor fans 20 comprise a lower set of fans 22 and an upper set of fans 24. The blades of fans 22 and fans 24 rotate in opposite direction to direct air in an upper direction out of the set of fans 20. Fans 22 and 24 can be sized for maximum efficiency. In particular, the impeller blades of the fans could be sized to consume the least amount of power while directing the most heat from the interior of the server systems of the rack. Shown in FIG. 2 is a pictorial view of the rack system of FIG. 1. As shown in FIG. 2, the plenum 16 is coupled to the back of rack 12. Plenum 16 is comprised of three surfaces, two side surfaces and a back surface. The fourth surface in the cross-sectional rectangle of the plenum is formed by the back of the rack 12. Fan assembly is shown coupled to the top of plenum 16.

As show in FIG. 3, racks 12 may be placed in a back-to-back configuration in which a plenum 32 is placed between the two racks, indicated at 30a and 30b. FIG. 3 is a sectional view of racks in a back-to-back configuration. Heated air from the server systems 38 in each of the racks is directed into the interior of the plenum and directed out of the plenum by the fan assembly 34. The racks and plenum may include a number of louvers 36, with each louver being associated with a slot in one of the racks for a server system. When a server system is removed from the rack or when a server system is not present in the rack, the louver is closed to prevent heated air from escaping through the unpopulated slot in the rack. The closing of the louver could occur on an automated basis upon the determination that a slot is empty or that a rack has been removed from the slot.

The louvers 36 may also be angled in a cascading fashion to optimize the air flow through the rack and plenum configuration by balancing the air pressure in each of the server systems to insure that heated air is directed out of each of the server systems and into the interior of the plenum. As indicated in FIG. 3, the louvers for slots at the bottom of the rack are more open than louvers at the top of the rack. Because the servers systems at the bottom of the rack are at a greater distance from the fans of the fan assembly, the louvers are more open to lower the air pressure at the outlet of the server system at the bottom of the rack. The server system at the top of the rack are closer to the fan assembly. For that reason, the louvers for these systems are biased towards being more closed and less open. By biasing the degree to which each louver is open or closed, the air pressure is equalized across each of the server systems, leading to a more even flow of air across each of the server system.

The use of a fan set at the exit of an external plenum reduces the reliance on the fans of the servers for the cooling of the interior of the server systems. In this way, the fans in the interior may be unnecessary. Alternatively, if a fan in a server system fails, the fan need not be replaced because of the presence of the fan set in the plenum. Because the fan in the server need not be immediately replaced, the server system can remain in operation. In addition, if a fan in the external fan set fails, the external fan can be easily replaced without disrupting the operation of any of the server systems. Although the present disclosure has been described in detail, it should be understood that various changes, substitutions, and alterations can be made hereto without departing from the spirit and the scope of the invention as defined by the appended claims.

What is claimed is:

1. A rack and plenum, comprising:
a rack having a front and a back;
a plenum coupled to the back of the rack, wherein the plenum includes an opening at the top of the plenum;
a fan assembly coupled to the opening at the top of the plenum.

2. The rack and plenum of claim 1, wherein the fan assembly comprises a first fan coupled to the top of the plenum and a second fan coupled to the top of the first fan.

3. The rack and plenum of claim 2, wherein the blades of the first fan rotate in the opposite direction of the blades of the second fan.

4. The rack and plenum of claim 1, wherein the fan assembly comprises a first row of fans coupled to the top of the plenum and a second row of fans coupled to the top of the first two of fans.

5. The rack and plenum of claim 2, wherein the blades of the fans of the first row of fans rotate in the opposite direction of the blades of the fans of the second row of fans.

6. The rack and plenum of claim 1, wherein the rack is populated with a plurality of computer systems.

7. The rack and plenum of claim 1,
wherein each slot of the rack is associated with a louver; and
wherein the degree to which the louver is open depends on the distance of the slot from the fan assembly.

8. The rack and plenum of claim 7, wherein the fan assembly assembly comprises multiple fans and wherein the activation of the fans in the fan assembly causes air to be drawn from the front of the computer systems and into the plenum and causes air to be directed out of the top of the plenum.

9. An air evacuation system for a rack, comprising:
a plenum having a opening at the top of the plenum;
a fan assembly coupled to the opening at the top of the plenum.

10. The air evacuation system for a rack of claim 9, wherein the fan assembly comprises a first fan coupled to the top of the plenum and a second fan coupled to the top of the first fan.

11. The air evacuation system for a rack of claim 10, wherein the blades of the fans of the first row of fans rotate in the opposite direction of the blades of the fans of the second row of fans.

12. The air evacuation system for a rack of claim 9, wherein the fan assembly comprises a first row of fans coupled to the top of the plenum and a second row of fans coupled to the top of the first two of fans.

13. The air evacuation system for a rack of claim 12, wherein the blades of the fans of the first row of fans rotate in the opposite direction of the blades of the fans of the second row of fans.

14. The air evacuation system for a rack of claim 9,
wherein plenum includes a plurality of louvers; and
wherein the degree to which the louver is open depends on the distance of the louver from the fan assembly.

15. The air evacuation system for a rack of claim 9,
wherein the fan assembly comprises a first row of fans coupled to the top of the plenum and a second row of fans coupled to the top of the first two of fans;
wherein the blades of the fans of the first row of fans rotate in the opposite direction of the blades of the fans of the second row of fans; and
wherein the plenum is comprised of a back coupled to two sides.

16. The air evacuation system for a rack of claim 15, wherein the activation of the fans of the fan assembly causes air to be drawn into the interior of the plenum and expelled from the interior of the fans out of the top of the plenum.

17. A method for cooling a set of computer systems housed within a rack, comprising,
providing a rack;
providing a plenum, wherein the plenum is comprised of two sides coupled to a back and wherein the plenum includes an opening at the top of the plenum;
providing a fan assembly coupled to the top of the plenum; and
activating the fan assembly to cause air to be drawn across the interior of the computer systems and out of the top of the plenum.

18. The method for cooling a set of computer systems housed within a rack of claim 17, wherein the fan assembly comprises a first fan coupled to the top of the plenum and a second fan coupled to the top of the first fan.

19. The method for cooling a set of computer systems housed within a rack of claim 18, wherein the blades of the first fan rotate in the opposite direction of the blades of the second fan.

20. The method for cooling a set of computer systems housed within a rack of claim 17, wherein the fan assembly comprises a first row of fans coupled to the top of the plenum and a second row of fans coupled to the top of the first two of fans.
